(19) United States
(12) Patent Application Publication
(10) Pub. No.: US 2026/0139377 A1
(43) Pub. Date: May 21, 2026

(54) SUBSTRATE PROCESSING DEVICE

(71) Applicant: JUSUNG ENGINEERING CO., LTD., Gwangju-si, Gyeonggi-do (KR)

(72) Inventors: Jae-Wuk SO, Yongin-si, Gyeonggi-do (KR); Jeong-Uk EOM, Hwaseong-si, Gyeonggi-do (KR); Min-Jin SONG, Yongin-si, Gyeonggi-do (KR); Hyun-Wook SHIN, Yongin-si, Gyeonggi-do (KR); Chul Joo HWANG, Seongnam-si, Gyeonggi-do (KR)

(21) Appl. No.: 19/123,389

(22) PCT Filed: Oct. 31, 2023
(86) PCT No.: PCT/KR2023/017100

§ 371 Date: Apr. 22, 2025

(30) Foreign Application Priority Data
Nov. 4, 2022 (KR) 10-2022-0145754

(51) Int. Cl. C23C 16/505

(52) U.S. Cl. CPC C23C 16/505

(57) ABSTRACT

A substrate processing apparatus according to an example embodiment includes: a chamber having a sidewall; a susceptor mounting a substrate inside the chamber; an upper dome covering an upper surface of the chamber and formed of a dielectric material; a lower dome covering a lower surface of the chamber and formed of a dielectric material; a liner disposed on internal side of the chamber and disposed between the upper dome and the lower dome; and an antenna disposed on the upper dome and generating inductively-coupled plasma. A ratio of a diameter of the antenna to a diameter of the substrate may be 80 percent to 120 percent.

### CROSS-REFERENCE TO RELATED APPLICATIONS

This application is a continuation of and claims priority to PCT/KR2023/017100 filed on Oct. 31, 2023, which claims priority to Korea Patent Application No. 10-2022-0145754 filed on Nov. 4, 2022, the entireties of which are both hereby incorporated by reference.

### TECHNICAL FIELD

The present disclosure relates to a substrate processing apparatus, and more particularly, to a plasma enhanced chemical vapor deposition apparatus for depositing a high-κ dielectric thin film by performing rapid substrate heating at a high temperature using a lamp heater.

### BACKGROUND ART

In semiconductor fabrication, a single-crystalline silicon thin film having the same crystal structure as a single-crystalline silicon substrate is deposited on the substrate. When the single-crystalline silicon thin film is grown, an inorganic insulating material such as a silicon oxide is deposited and patterned to form a single-crystalline region only in a silicon-exposed portion of a semiconductor surface, which is referred to as selective epitaxial growth (SEG).

In addition, in manufacturing of a thin-film solar cell on a large-area substrate, a P-type layer receiving sunlight, an I-type layer forming an electron-hole pair, and an N-type layer serving as an opposite electrode of the P-type layer are basic elements. Similarly, a liquid crystal display (LCD) device is based on an array element and a color filter element, respectively formed on an array and a color filter substrate.

A photolithography process needs to be performed several times to fabricate a thin film element for a solar cell and a liquid crystal display device. Such a photolithography process includes a thin film deposition process, a photosensitive layer coating process, an exposure and development process, and an etching process. In addition, such a photolithography process accompanies various processes such as a cleaning process, an attaching process, a cutting process, or the like.

Plasma-enhanced chemical vapor deposition (hereinafter referred to as “PECVD”) is a process by which a thin film is formed while reaction gas is excited into a plasma state inside a chamber by applying a radio-frequency (RF) high voltage to an antenna or an electrode.

Recently, to prevent particles or byproducts generated during a deposition process using PECVD from adhering to an inner wall of a chamber, the inner wall is designed with quartz, and an upper dome and a lower dome are designed with quartz in an upper portion and a lower portion of the chamber.

In a deposition process using such PECVD, a pressure inside a chamber is maintained at several mTorr and is maintained in an ultra-high vacuum state of 10E−9 Torr in a base vacuum state to significantly decrease the number of particles or byproducts generated during the deposition process and to reduce a time for the deposition process, resulting in an advantage for improving production yield.

Such plasma-enhanced chemical vapor deposition depends on a temperature distribution of a substrate and characteristics of plasma.

### DISCLOSURE OF THE INVENTIVE CONCEPT

### Technical Problem

An aspect of the present disclosure is to provide a plasma-enhanced chemical vapor deposition apparatus having an upper dome and a lower dome. In the plasma-enhanced chemical vapor deposition apparatus, a size of an antenna generating plasma is adjusted by a ratio to a diameter of a substrate to adjust a deposition profile of a high-κ dielectric thin film.

An aspect of the present disclosure is to prevent process gas, injected into an upper space between the upper dome and the substrate, from flowing into a lower space below a susceptor by using a structure of a liner disposed between the upper dome and the lower dome and a shape of the susceptor.

### Technical Solution

A substrate processing apparatus includes: a chamber having a sidewall; a susceptor mounting a substrate inside the chamber; an upper dome covering an upper surface of the chamber and formed of a dielectric material; a lower dome covering a lower surface of the chamber and formed of a dielectric material; a liner disposed on internal side of the chamber and disposed between the upper dome and the lower dome; and an antenna disposed on the upper dome and generating inductively-coupled plasma. A ratio of a diameter of the antenna to a diameter of the substrate may be 80 percent to 120 percent.

In an example embodiment, the antenna may include two one-turn unit antennas, the two one-turn unit antennas may be disposed to overlap each other on an upper surface and a lower surface, the two one-turn unit antennas may be connected in parallel to radio-frequency (RF) power, and a width direction of the one-turn unit antenna may stand upright vertically.

In an example embodiment, the one-turn unit antenna may be in the form of a strip line having a width greater than a thickness, a width direction of the one-turn unit antenna may stand upright vertically, and a ratio of a width W to a thickness t (W/t) may be 10 or more.

In an example embodiment, each of the pair of one-turn antennas may have one end connected to a pair of vertical power supply lines extending vertically, and the pair of vertical power supply lines may be connected to each other by a horizontal power supply line and then connected to the RF power.

In an example embodiment, the substrate processing apparatus may further include: a clamp disposed to be in contact with an upper surface of the chamber and to cover an edge of the upper dome; an electromagnetic shielding portion disposed on the clamp and disposed to surround the antenna; and a ground fixing portion fixing the other end of each of the pair of one-turn antennas to the electromagnetic shielding portion. The ground fixing portion may extend from the upper surface of the one-turn antenna in a radial direction, then extend to the lower surface, and then extend again from the lower surface in the radial direction.

In an example embodiment, the substrate processing apparatus may further include: an insulating fixing portion extending parallel to the ground fixing portion and coupled to a lower surface of the one-turn antenna to be fixed to the electromagnetic shielding portion.

### Advantageous Effects

As set forth above, a substrate processing apparatus according to an example embodiment may be a plasma-enhanced chemical vapor deposition apparatus. In the plasma-enhanced chemical vapor deposition apparatus, a size of an antenna generating plasma may be adjusted by a ratio to a diameter of a substrate to adjust a deposition profile based on the size of the antenna. According to the present disclosure, an antenna (having a diameter of 356 mm), larger than a diameter of a 300 mm substrate, has achieved a uniformity of 3.1 percent for an HfZrO thin film (an HZO thin film).

### BRIEF DESCRIPTION OF THE DRAWINGS

FIG. 1 is a conceptual diagram illustrating a home position in a plasma-enhanced chemical vapor deposition apparatus according to an embodiment of the present disclosure.

FIG. 2 is a conceptual diagram illustrating an elevation position in the plasma-enhanced chemical vapor deposition apparatus of FIG. 1.

FIG. 3 is a conceptual diagram, taken in another direction, illustrating the plasma-enhanced chemical vapor deposition apparatus of FIG. 1.

FIG. 4 is a perspective view illustrating an antenna of the plasma-enhanced chemical vapor deposition apparatus of FIG. 1.

FIG. 5 is a plan view illustrating the antenna of FIG. 4 when viewed toward an upper dome.

FIG. 6 is a plan view illustrating an antenna according to another embodiment of the present disclosure.

### MODE FOR CARRYING OUT THE INVENTIVE CONCEPT

To deposit a high-κ dielectric thin film, a substrate needs to be heated to about 300 degrees Celsius. In addition, to secure the uniformity of plasma or the deposition uniformity of the high-κ dielectric thin film, conventional attempts have been made to secure the uniformity of a process by changing a size of a chamber to a size of a fixed antenna. However, changing the size of the chamber is inappropriate to an atomic layer deposition process that significantly reduce a process volume, and adjusting the size of the chamber is not effective in terms of time and costs.

According to the present disclosure, process uniformity may be easily secured by adjusting the size of the antenna while the volume of the chamber is fixed. For example, when a diameter of the antenna was about 120 percent of a size of a substrate, the uniformity of the high-κ dielectric thin film was achieved at 3.1 percent.

According to the present disclosure, a chemical vapor deposition apparatus having an upper dome and a lower dome may use a liner to prevent unwanted deposition of a thin film on an inner wall of a chamber. The liner may be periodically replaced or cleaned.

A chemical vapor deposition apparatus having an upper dome and a lower dome according to an example embodiment may injects process gas into an upper space defined by the upper dome and a susceptor, and may exhaust the process gas through an opening of the liner connected to the upper space. When the process gas supplied to the upper space is introduced into a lower space defined by the lower dome and the susceptor, an abnormal thin film may be deposited on the lower dome and the liner.

The liner according to the present disclosure may include an upper liner having a constant inner diameter, a lower liner continuously connected to the upper liner and having a constant inclination angle and increasing inner diameter, and a connection portion having a curve between the upper liner and the lower liner.

The susceptor according to the present disclosure may have has a thickness of 30 mm or more, and a side surface of the susceptor may have an angle of inclination. Additionally, the liner may have an inclined portion to maintain a constant distance from the inclined side surface of the susceptor.

When the susceptor is in a process position (or an up-position) to process a substrate, the susceptor may be lifted to a connection portion of the liner. A distance (or a gap) between the lower liner and the inclined side surface of the susceptor may be maintained at a level of 2 mm. Such a narrow gap may provide low conductance to inhibit the process gas in the upper space from moving into the lower space.

A first opening for exhausting the process gas and a second opening for entering and exiting the substrate may be formed in the lower liner, and may be in contact with the connection portion. Accordingly, when the susceptor is in the process position, the inclined side surface of the susceptor may be disposed such that the first opening and the second opening oppose each other, allowing the first opening and the second opening to be substantially closed. However, the connection portion may form a space on the upper side surface of the susceptor, and the connection portion and the first opening may provide a path for exhausting the process gas.

The susceptor may have a sufficient thickness and a height, larger than a height of the first opening. In the process position, an upper surface of the susceptor may be set to be substantially even with an upper surface of the first opening, and a lower surface of the susceptor may be set to be lower than a lower surface of the first opening. The gap between the inclined side surface of the susceptor and the lower liner may be maintained at a level of 2 mm. Accordingly, the process gas introduced toward the first opening may not be introduced into the lower space due to the low conductance.

The susceptor according to the present disclosure may have a thickness sufficient to cover the first opening and an inclined side surface and may inhibit the process gas, injected into the upper space, from flowing into the lower space. Accordingly, the lower space may suppress the generation of an abnormal thin film and particles. In addition, the inclined side surface of the susceptor may prevent an infrared light from introducing into the upper space to efficiently heat the susceptor.

According to the present disclosure, the susceptor may be rotated to achieve process uniformity.

According to the present disclosure, purge gas may be supplied to the lower dome and process gas may be supplied to the upper space between the upper dome and the susceptor. Thus, the process gas may be prevented from flowing into the lower dome to suppress deposition of an abnormal thin film on the lower dome.

According to the present disclosure, when the susceptor is in the process position, the upper space may be smaller than the lower space. To this end, a height of the lower liner may be larger than a height of the upper liner. As the upper space is reduced, a deposition rate may increase.

In the present disclosure, the lower liner may have an inclined surface to inject purge gas, supplied from the lower dome, in a direction of the upper dome and to install a larger number of lamp heaters. The gap between the susceptor and the lower liner is maintained to be narrow, so that the purge gas supplied from the lower dome may be injected toward the upper dome to create a pressure difference. Due to the narrow gap between the susceptor and the lower liner, the process gas injected into the upper space may stay only in the upper space to prevent contamination of the lower space.

In the present disclosure, an antenna for inductively-coupled plasma may be disposed to be spaced apart from the upper dome, conducting wires constituting the antenna may be in the form of strip lines, and the strip lines may be vertically aligned in a width direction. Accordingly, infrared light incident from a lower dome may be minimally incident on the antenna. As a result, the antenna may suppress heating by the infrared light, and infrared light reflected from an electromagnetic shielding portion may significantly reduce a shadow.

In the present disclosure, an electromagnetic shielding portion surrounding an antenna and shielding an electromagnetic wave may be plated by gold plating, so that infrared light may be reflected and be then re-incident on the substrate. In addition, the electromagnetic shielding portion may have a cylindrical shape, rather than a dome shape, to reduce re-incident heating of the antenna caused by reflection of the infrared light.

In the present disclosure, a lamp heater disposed below the lower dome may be a ring-shaped lamp heater and may be provided in plural. The ring-shaped lamp heaters may be grouped together to independently control power to uniformly heat a substrate.

In the present disclosure, a turbomolecular pump (TMP) connected to an exhaust portion of a chamber may allow base vacuum to be maintained inside the chamber, and may generate stable plasma at a pressure of several Torr or less even during a process.

Plasma-assisted chemical vapor deposition according to the present disclosure may reduce performance degradation caused by infrared heating of an inductively-coupled plasma antenna disposed on an upper dome and may provide infrared light, reflected from an antenna housing, back to a substrate to form a uniform thin film on the substrate at high speed.

When a lamp heater is applied for a process temperature of 300 degrees Celsius, the antenna generating inductively-coupled plasma in a process container may be heated by the lamp heater and a resistance value increases as temperature rises. Accordingly, the antenna may not generate efficient inductively-coupled plasma due to consumption of energy through ohmic heating. In addition, the antenna may form a shadow for infrared light, reflected from an electromagnetic shielding portion, to provide non-uniformity of temperature to the substrate. To achieve process stability, the electromagnetic shielding portion may be heated to shield electromagnetic waves while maintaining the antenna at a constant temperature.

In addition, the electromagnetic shielding portion disposed to surround the antenna may reflect a portion of the infrared light emitted from the lamp heater, and the remaining infrared light may be absorbed by the electromagnetic shielding portion and heat, resulting in reduced reliability. A spatially non-uniform temperature distribution in the electromagnetic shielding portion may provide spatially non-uniform blackbody radiation. Therefore, the electromagnetic shielding portion may use an additional resistive heater to heat to a uniform temperature and may provide spatially uniform blackbody radiation. The electromagnetic shielding portion may be heated to 200 degrees Celsius to 600 degrees Celsius to increase heat loss when it is brought into direct thermal contact with the chamber. Accordingly, the electromagnetic shielding portion may be thermally insulated from the chamber to significantly reduce the heat loss. For example, a thermal insulating spacer may be disposed between the electromagnetic shielding portion and the chamber to reduce the heat loss of the electromagnetic shielding portion. The electromagnetic shielding portion may be electrically grounded through an additional conductive line. The thermal insulating spacer may have a ring shape, and may be formed of a ceramic material. The insulating spacer may be formed of a porous ceramic material.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

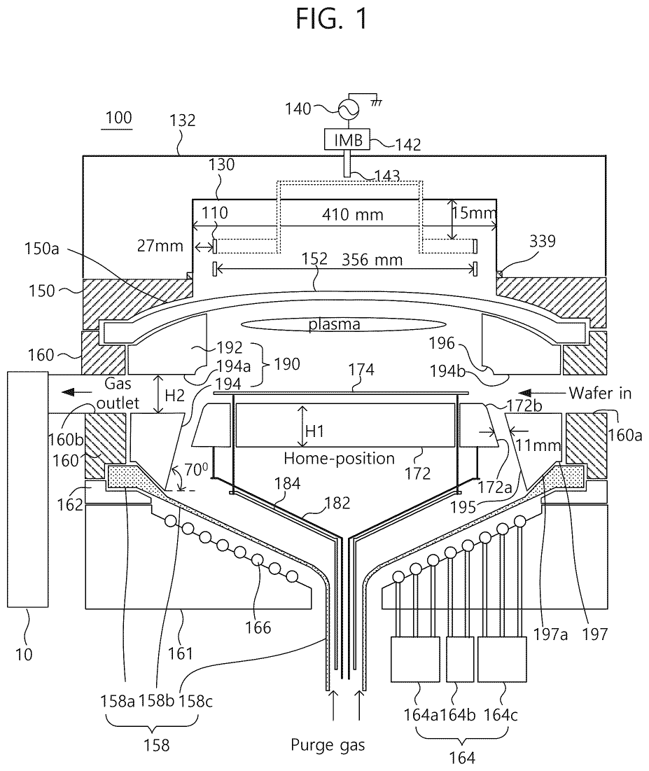

FIG. 1 is a conceptual diagram illustrating a home position in a plasma-enhanced chemical vapor deposition apparatus according to an embodiment of the present disclosure.

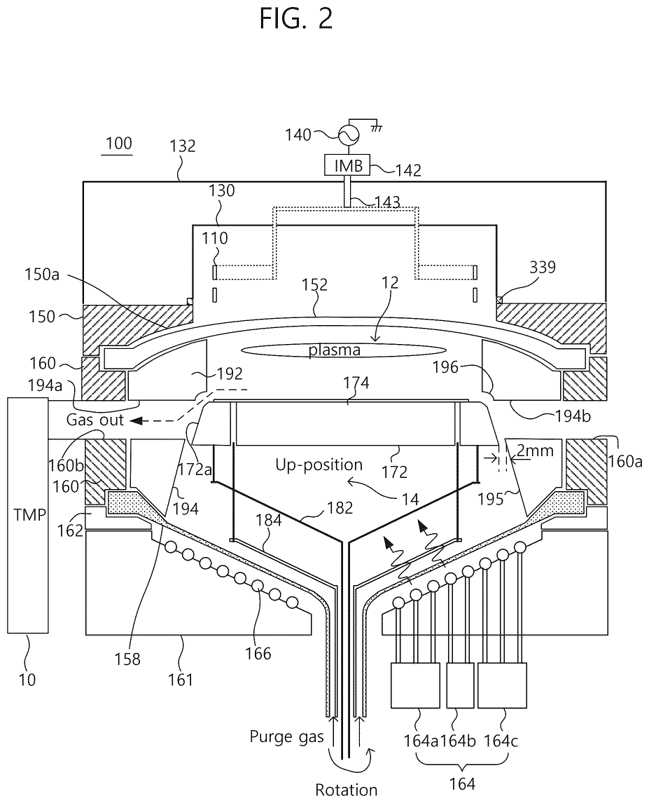

FIG. 2 is a conceptual diagram illustrating an elevation position in the plasma-enhanced chemical vapor deposition apparatus of FIG. 1.

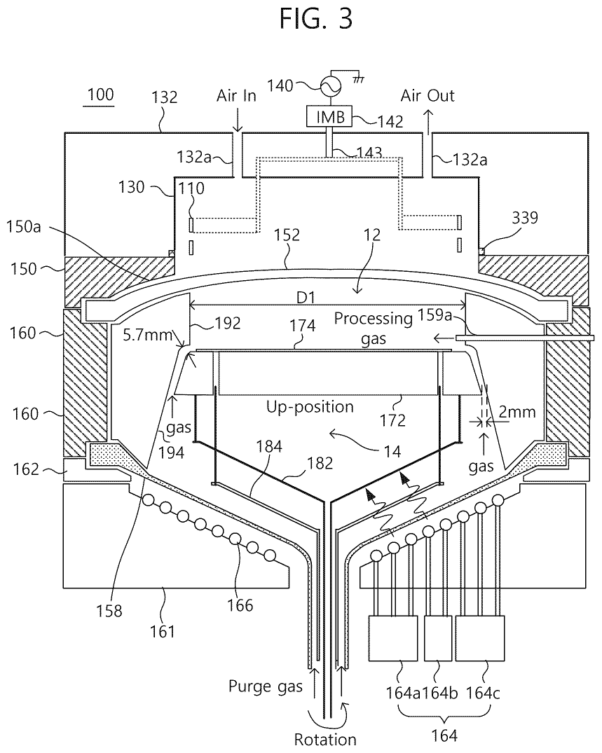

FIG. 3 is a conceptual diagram, taken in another direction, illustrating the plasma-enhanced chemical vapor deposition apparatus of FIG. 1.

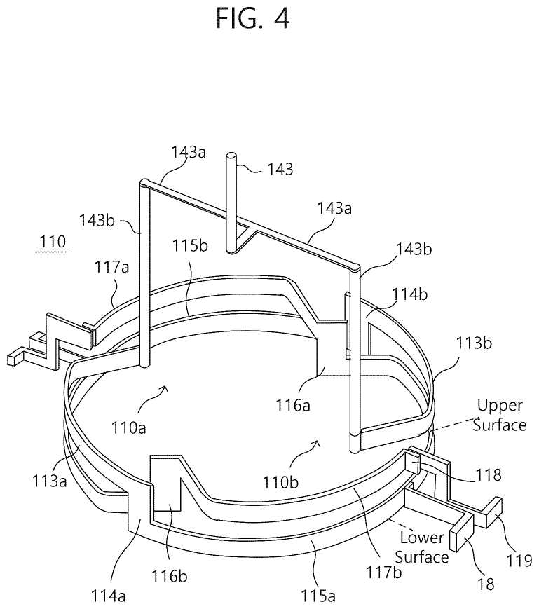

FIG. 4 is a perspective view illustrating an antenna of the plasma-enhanced chemical vapor deposition apparatus of FIG. 1.

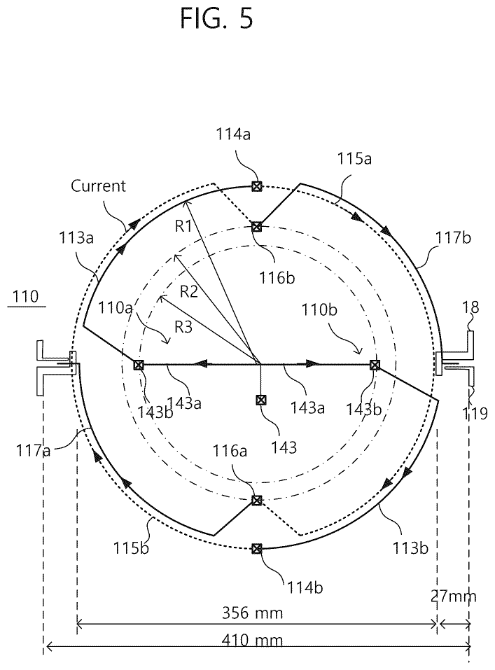

FIG. 5 is a plan view illustrating the antenna of FIG. 4 when viewed toward an upper dome.

Referring to FIGS. 1 to 5, a plasma-enhanced chemical vapor deposition apparatus 100 according to an example embodiment may include a chamber 160 having a sidewall; a susceptor 172 mounting a substrate inside the chamber 160; an upper dome 152 covering an upper surface of the chamber 160 and formed of a dielectric material; a lower dome 158 covering a lower surface of the chamber and formed of a dielectric material; a liner 190 disposed on an inner side of the chamber 160 and disposed between the upper dome 152 and the lower dome 158; and an antenna disposed on the upper dome 152 and generating inductively-coupled plasma. A ratio of a diameter of the antenna to a diameter of the substrate may be 80 percent to 120 percent.

The chamber 160 may be formed of a conductive material, and may have a cylindrical internal shape and a cuboidal external shape. The chamber 160 may be cooled by cooling water. The chamber 160, the upper dome 152, and the lower dome 158 may be coupled to provide a sealed space. The chamber 160 may include a substrate entrance 160a, formed on a side surface of the chamber 160, and an exhaust port 160b formed on a side surface opposing the substrate entrance 160a. The exhaust port 160b may be connected to a low-vacuum pump and a high-vacuum pump 10. The high-vacuum pump 10 may be a turbomolecular pump. The high-vacuum pump may maintain a low base pressure, and may maintain a pressure of several Torr or less even during a process. An upper surface of the exhaust port 160b may be disposed on an upper level than or the same level as an upper surface of the substrate entrance 160a.

For example, when the upper surface of the exhaust port 160b is disposed on the same level as the upper surface of the substrate entrance 160a, an upper surface of the susceptor 172 may be changed to the same position as the upper surfaces of the exhaust port 160b and the substrate entrance 160a during a process. Accordingly, symmetry inside the chamber 160 may be improved and a flow of process gas may be improved to provide uniform thin film deposition.

The susceptor 172 may mount the substrate 174 when the substrate 174 is introduced through the substrate entrance 160a formed on the side surface of the chamber 160. The susceptor 172 may have a disk shape. The susceptor 172 may have a thickness of 30 mm or more. The susceptor 172 may have a thickness of, in detail, 40 mm or more. The susceptor 172 may include a curved portion 172b curved on an upper surface of the susceptor 172; and an inclined side surface 172a continuously connected to the curved portion 172b. A first angle of inclination of the inclined side surface 172a of the susceptor may be 70 degrees. A diameter of the substrate 174 may be 300 mm.

The susceptor 172 may have the same plate shape as the substrate 174, and may be formed of ceramic or graphite having improved thermal conductivity. The susceptor 172 may be heated by infrared light incident from a lower portion, and may heat the substrate 174 through heat transfer. During a process, the upper surface of the susceptor 172 may be substantially the same as an upper surface of the exhaust port 160b and the substrate entrance 160a. The susceptor 172 may be rotated to improve azimuthal symmetry.

A first lifter 184 may extend along a central axis of the lower dome 158, and may include a first lifter body having a tripod shape and a first lift pin. The first lifter 184 and a second lifter 182 may have a coaxial structure. When the substrate 174 is transferred into the chamber 160, the first lifter 184 may be lifted from a down-position or a home position to support the substrate 174. Then, the first lifter 184 may be lowered to place the substrate 174 on the susceptor 172. A material of the first lifter 184 may be quartz or a metal. The first lifter 184 may be vertically moved by a driving shaft.

The second lifter 182 may extend along the central axis of the lower dome 158, and may include a second lifter body having a tripod shape and a second lift pin. The second lifter 182 may lift the susceptor 172, on which the substrate 174 is mounted, from the home position (or the down-position) to a process position (or an up-position). In the process position, the upper surface of the susceptor 172 may be disposed in the same plane as an upper surface of a second opening 194b for introducing the substrate 174 in the liner 194. In addition, in the process position, the upper surface of the susceptor 172 may be disposed in substantially the same plane as an upper surface of the first opening 194a for exhausting gas in the liner 194. Accordingly, the inclined side surface 172a of the susceptor 172 may be disposed to close the first opening 194a and the second opening 194b. A material of the second lifter 182 may be quartz or a metal. The second lifter 182 may be vertically moved by a driving shaft. The second lifter 182 may be rotated to rotate the susceptor 172.

The upper dome 152 may include quartz or sapphire as a transparent dielectric material. The upper dome 152 may be inserted into and coupled to a raised spot formed on the upper surface of the chamber 160. In the upper dome 152, a coupling portion coupled to the chamber 160 for vacuum sealing may have a washer shape. The upper dome 152 may have an arc shape or an elliptical shape. The upper dome 152 may allow infrared light, incident from a lower portion, to pass therethrough. Infrared light, reflected from the electromagnetic shielding portion 130, may pass through the upper dome 152 and may then be re-incident on the substrate 174.

The lower dome 158 may include quartz or sapphire as a transparent dielectric material. The lower dome 158 may have a funnel-shaped lower dome body 158b, a washer-shaped coupling portion 158a coupled to a raised spot formed on the lower surface of the chamber 160, and a cylindrical pipe 158c connected to a center of the lower dome body 158b. The lower dome 158 may be inserted into and coupled to the raised spot formed on the lower surface of the chamber 160. In the lower dome 158, the coupling portion 158 a coupled to the chamber 160 to provide vacuum sealing may have a washer shape. The driving shaft of the first lifter and the driving shaft of the second lifter may be disposed to be inserted into the cylindrical pipe 158c. Purge gas, supplied through the lower dome 158, may be supplied through a flow path. The flow path may be a cylindrical pipe 158c. The purge gas may be inert gas such as argon (Ar).

The liner 190 may be disposed inside the chamber 160 and between the upper dome 152 and the lower dome 158. The liner 190 may include an inclined portion 195 having an inclined inner side surface. A second angle of inclination of the inclined portion of the liner 190 may be the same as the first angle of inclination of the inclined side surface 172a of the susceptor 172. Each of the first angle of inclination and the second angle of inclination may be 70 degrees. When the first angle of inclination and the second angle of inclination are the same, the inclined side surface 172a of the susceptor 172 and the inclined portion 195 of the liner 190 may be maintained at a constant distance. When the susceptor 172 is in the process position, the inclined side surface 172a of the susceptor 172 and the inclined portion 195 of the liner 190 may be maintained at a minimum gap of about 2 mm.

The liner 190 may include an upper liner 192 having a first inner diameter D1 and disposed adjacent to the upper dome 152; and a lower liner 194 continuously connected to the upper liner 192 and having an inclined portion 195 with an increased inner diameter. The lower liner 194 may include a first opening 194a disposed adjacent to a lower surface of the upper liner 192 to exhaust gas; and a second opening 194b disposed on the other side opposing the first opening 194a to provide a path of a substrate. The liner 190 may further include a connection portion 196 curved between the upper liner and the lower liner. The upper liner 192 and the lower liner 194 may be integrally formed. The liner 190 may include an upper liner having a constant inner diameter, a connection portion having a curvature and an increased diameter at the upper liner, and a lower liner having a constant angle of inclination in the bonding portion.

When the susceptor 172 is in the down-position, a distance between the inclined portion 195 of the lower liner 194 and the inclined side surface 172a of the susceptor 172 may be 7 mm to 13 mm, in detail, at a level of 11 mm.

When the susceptor 172 is in the up-position, a distance between the inclined side surface 172a of the susceptor 172 and the inclined portion 195 of the liner 190 may be 1 mm to 3 mm, in detail, at a level of 2 mm. Such a narrow gap may reduce an area of a cross-section, through which fluid may flow, to provide low conductance. Tens of millimeters or more, a thickness of the susceptor 172, may provide lower conductance to the fluid.

When the susceptor 172 is in the up-position, a vertical distance between the curved portion 172b of the susceptor 172 and the connection portion 196 of the liner may be 4 mm to 7 mm, in detail, 5.7 mm. An outer diameter of the upper surface of the susceptor 172 may be substantially the same as an inner diameter D1 of the upper liner 192 or may be several millimeters larger than the inner diameter D1. When the susceptor 172 is lifted such that the upper surface of the susceptor 172 matches an upper surface of the first opening, the connection portion 196 may provide an exhaust path through which process gas is discharged to the first opening.

The liner 190 may be formed of a transparent or opaque dielectric material. The liner 190 may be formed of quartz, alumina, sapphire, or aluminum nitride. The liner 190 may be selected as a material inhibiting deposition of an abnormal thin film. When the liner 190 is contaminated, it may be decomposed and cleaned. The liner 190 may include an upper liner and a lower liner.

The upper liner 192 has an overall ring shape, and the upper surface of the upper liner 192 may be a curved surface having the shape of the upper dome. An external upper surface of the upper liner 192 may have a planar portion. An inner diameter of the upper liner 192 may be D1.

The upper liner 192 may include at least one process gas supply unit 159a supplying process gas through a side surface of the upper liner 192. The process gas supply unit 159a may protrude from an internal side surface of the upper liner 192. For example, the process gas supply unit 159a may include a first process gas supply unit 159a, supplying first process gas such as SiH4, and a second process gas supply unit 159a supplying second process gas.

The first process gas supply unit 159a may protrude more from a side surface of the upper liner 192 such that the first process gas, such as SiH4, is more exposed to plasma. The second process gas supply unit 159a may protrude less from the side surface of the upper liner 192 such that the second process gas, such as hydrogen gas (H2), is less exposed to plasma. The purge gas is introduced into the upper space 12 of the chamber 160 from the lower dome 158, so that it may be uniformly supplied on a circumference to have a spatially uniform pressure distribution.

The connection portion 196 may be a recessed structure having a curvature on a lower internal side surface of the upper liner 192. The curved portion 172b of the susceptor 172 may oppose the connection portion 196 with a predetermined gap.

The lower liner 194 may be disposed inside the chamber 160 and have a cylindrical shape surrounding an internal peripheral surface of an upper edge of the lower dome 158. The lower liner 194 may include an inclined lower external surface 197a for coupling to the lower dome 158 and an inclined portion 195 inclined on an internal side surface. The inclined lower external surface 197a may have a planar portion 197 on an external side. The second angle θ of inclination of the inclined portion may be about 70 degrees. The lower liner 194 may have a first opening 194a, formed on an internal surface adjacent to the upper liner 192 to exhaust gas, and a second opening 194b formed on the other side opposing the first opening 194a to provide a path of a substrate. The first opening 194a and the second opening 194b may be formed in the inclined portion 195. The first opening 194a may be aligned with the exhaust portion, and the second opening 194b may be aligned with the substrate entrance. When the susceptor 172 is disposed in the up-position, the first opening 194a and the second opening 194b may be substantially closed by the susceptor 172 to inhibit the process gas in the upper space 12 from moving to the lower space 14 defined by the susceptor 172 and the lower dome 158. The first opening 194a, the connection portion 194as, and the curved portion 172b of the susceptor 172 may provide a path through which the process gas may flow.

An insulation portion 162 may be disposed between the lower surface of the chamber 160 and the reflector 161, and may have a ring shape. The insulation portion 162 may reduce heat transfer from the heated reflector 161 to the chamber 160. The insulation portion 162 may be formed of a ceramic material. An upper surface of the insulation portion 162 may have a raised spot. The raised spot of the insulation portion 162 and the raised spot of the lower surface of the chamber 160 may accommodate and vacuum-seal the washer-shaped coupling portion 158a of the lower dome 158.

The concentric lamp heater 166 may include a plurality of concentric ring-shaped lamp heaters, and may be connected to a power supply 164. The concentric ring-shaped lamp heaters may be arranged at regular intervals along the inclined surface of the lower dome 158. The concentric ring-shaped lamp heaters may be divided into three groups and may receive power independently from each other. The concentric ring-shaped lamp heater may be aligned by being inserted into a ring-shaped groove formed in the inclined surface of the reflector 161. For example, the concentric lamp heater 166 may be a halogen lamp heater, and may include eight lamp heaters. Lower three lamp heaters may constitute a first group, intermediate two lamp heaters may constitute a second group, and upper three lamp heaters may constitute a third group. The first group may be connected to a first power supply 164a, the second group may be connected to a second power supply 164b, and the third group may be connected to a third power supply 164c. The first, second, and third power supplies 164a, 164b, and 164c may be independently controlled to uniformly heat a substrate.

The reflector 161 may support a lower surface of the insulating portion 162 and may mount the lamp heater. An inclined surface, on which the lamp heater 166 is mounted, may have a conic shape to be maintained at a predetermined distance from the inclined surface of the lower dome 158. The reflector 161 may be formed of a conductive material, and may be cooled by cooling water.

A clamp 150 may be disposed to be in contact with the upper surface of the chamber 160 and to cover an edge of the upper dome 152. The clamp 150 may be a portion of the chamber 160 performing the same function as the lid of the chamber 150. The clamp 150 may be formed of a conductive material, and may be cooled by cooling water. A lower surface of the clamp 150 may be provided with a raised spot to be coupled to the washer-shaped coupling portion of the upper dome 152, and a curved portion 150a to cover a portion of the curved portion of the upper dome 152. The curved portion 150a of the clamp 150 may be plated with gold to reflect infrared light. An inner diameter of the clamp 150 may be substantially the same as or larger than an internal diameter D1 of the upper liner 154. In addition, the inner diameter of the clamp 150 may be the same as a diameter of the electromagnetic shielding portion 130. The inner diameter of the electromagnetic shielding portion 130 may be 410 mm.

The antenna 110 may include two one-turn unit antennas 110a and 110b. The antennas 110 may be disposed to overlap each other on an upper surface and a lower surface, the one-turn unit antenna may be in the form of a strip line having a width greater than a thickness, and a width direction of the one-turn antenna may stand upright vertically. The two one-turn unit antennas 110a and 110b may be connected in parallel to a radio-frequency (RF) power supply 140. The RF power supply 140 may supply RF power to the antenna 110 through an impedance matching box (IMB) 142 and a power supply line 143. The antenna 110 may include two one-turn unit antennas, the two one-turn unit antennas may be disposed to overlap each other on an upper surface and a lower surface, and the two one-turn unit antennas may be connected in parallel to an RF power supply 140, and a width direction of the one-turn unit antenna may stand upright vertically.

The power supply line 143 may be connected to a T-shaped horizontal power supply line 143a to symmetrically branch out. One end of each of a pair of one-turn antennas may be connected to a pair of vertically extending vertical power supply lines 143b. The pair of vertical power supply lines 143b may be connected to each other by the horizontal power supply line 143a and then connected to the RF power supply 140. The pair of vertical power supply lines 143b may be disposed through the electromagnetic shielding portion 130. The horizontal power supply line 143a may be disposed outside the electromagnetic shielding portion 130.

An antenna, through which RF current flows, should have a sufficient cross-sectional area for high current, and should form a closed loop to generate sufficient magnetic flux. In addition, a plurality of turns are required to secure sufficient magnetic flux or high inductance. Therefore, a stack structure is required. However, an antenna having a width standing upright occupies a large space and is disadvantageous in securing sufficient magnetic, so that the antenna is not conventionally used.

In the present disclosure, the antenna 110 may use a vertically standing strip line such that ultraviolet light, incident from an upper portion or a lower portion of the antenna 110, is absorbed to significantly reduce an increase in resistance caused by heating. The antenna 110 may provide high light transmittance with respect to infrared light.

In addition, an antenna may be coated with gold (Au) or silver (Ag) to increase infrared reflection. In addition, an antenna having a two-layer structure may be used to secure sufficient magnetic flux. In the one-turn unit antenna, a position supplied with RF power may be disposed on an upper surface to reduce power loss caused by capacitive coupling. An aspect ratio (a ratio of width W to thickness t (W/t)) of the strip line may be 10 or more. The strip line may have a thickness of several millimeters and a width of several centimeters. Since the standing strip line structure does not impede a flow formed by introduction of air, the standing strip line structure may provide smooth air cooling. In addition, the infrared light reflected from the electromagnetic shielding portion may significantly reduce a shadow formed by the antenna.

The lower surface of the antenna 110 may be substantially the same plane as an upper surface of the clamp 150, and may be higher than a highest position of the upper dome 152. Accordingly, the antenna 110 is not in direct contact with the upper dome 152, so that the upper dome 152 may not be directly heated by heat transfer. The two one-turn unit antennas 110a and 110b may be rotated 180 degrees to overlap each other. Each of the one-turn unit antennas 110a and 110b may be disposed on the lower surface in a predetermined section and disposed on the upper surface in the other sections.

The one-turn unit antenna 110a/110b may include a radial portion 112a/112b connected to the vertical power supply line 143b and extending from the upper surface by rotating 90 degrees clockwise along a circumference having a first radius R1; a first vertical extension portion 114a/114b changing a placement plane from the upper surface to the lower surface in the first curved portion; a second curved portion 115a/115b rotating 180 degrees clockwise along the circumference having the first radius R1 in the first vertical extension portion; a second vertical extension portion 116a/116b continuously connected to the second curved portion, changing a radius from the first radius R1 to a second radius R2 smaller than the first radius R1, changing a placement plane from the lower surface to the upper surface, and changing a radius from the second radius R2 to the first radius R1; and a third curved portion 117a/117b extending from the upper surface by rotating 90 degrees clockwise along the circumference having the first radius R1 from the second vertical extension portion. The third curved portion 117a/117b may be connected to a ground portion 118 extending in the radial direction. A third radius of a circle connecting the pair of vertical power supply line 143b may be R3. The third radius R3 may be smaller than the second radius R2. The pair of vertical power supply lines 143b may extend through the upper surface of the electromagnetic shielding portion 130.

The ground fixing portion 119 may fix the other end of each of the pair of one-turn antennas to the electromagnetic shielding portion. The ground fixing portion 119 may be electrically connected to the ground portion 118 and may be connected to the electromagnetic shielding portion 130 by changing the placement plane to the lower surface of the antenna. The ground fixing portion 119 may be formed of a conductive material, and may be electrically connected to the electromagnetic shielding portion 130. The ground fixing portion 119 may extend in the radial direction from the upper surface of the one-turn antenna, then extend to the lower surface, and then extend again in the radial direction from the lower surface. The third curved portion 117a/117b may include a ground portion 118 extending in a direction, and one end of the ground fixing portion 119 may be screwed to the ground portion 118. The ground fixing portion 119 may have the same strip line structure as the antenna. The other end of the ground fixing portion 119 may be bent in an azimuth direction to be inserted into the internal surface of the electromagnetic shielding portion 130, and may be screwed to the electromagnetic shielding portion 130. The ground fixing portion 119 may provide a symmetrical structure while reducing parasitic inductance in the curved structure.

An insulating fixing portion 18 may extend in the radial direction parallel to the ground fixing portion 119, and may be coupled to a lower surface of the one-turn antenna to be fixed to the electromagnetic wave shielding portion 130. The insulating fixing portion 18 may provide mechanical stability to the antenna 110. The insulating fixing portion 18 may be formed of a dielectric material such as ceramic or plastic. One end of the insulating fixing portion 18 may be bent in the azimuth direction and screwed to the second curved portions 115a and 115b, and the other end of the insulating fixing portion 18 may be bent in the azimuth direction, to be inserted into an internal side surface of the electromagnetic shielding portion 130, and screwed to the electromagnetic shielding portion 130.

The electromagnetic shielding portion 130 may be disposed on the clamp 150 and disposed to surround the antenna 110, and an internal surface of the electromagnetic shielding portion 130 may be coated with gold (Au). The electromagnetic shielding portion 130 may shield electromagnetic waves emitted from the antenna 110, and may reflect infrared light emitted from the lamp heater. The electromagnetic shielding portion 130 may be heated by a heater incorporated therein. A temperature of the electromagnetic shielding portion 130 may be 200 degrees Celsius to 600 degrees Celsius. The electromagnetic shielding portion 130 may shield electromagnetic waves emitted by the antenna 110. The electromagnetic shielding portion 130 may be formed of a conductive material and may be heated by a heater buried therein. The electromagnetic shielding portion 130 may be grounded by an additional conducting wire.

An inner diameter of the electromagnetic shielding portion 130 may be 410 mm, an outer diameter distance between the antenna 110 and the electromagnetic shielding portion 130 may be 27 mm, and a vertical distance between the antenna 110 and the electromagnetic shielding portion 130 may be 15 mm. A diameter of the antenna may be 356 mm. The inner diameter of the electromagnetic shielding portion 130 may be substantially the same as the inner diameter of the clamp 150. For example, when the distance between the antenna 110 and the electromagnetic shielding portion 130 in the outer diameter direction is at a level of 27 mm, thin film uniformity may be significantly increased to 3.1 percent.

The insulating spacer 339 may be thermally insulated from the electromagnetic shielding portion 130 and the upper surface of the chamber 160. The insulating spacer 339 may have a ring shape formed of ceramic material. The insulating spacer 339 may be covered with a wire mesh gasket. The wire mesh gasket may significantly reduce heat transfer while electrically connecting the electromagnetic shielding portion 130 and the clamp 150.

A cooling housing 132 may be disposed to be spaced apart from the electromagnetic shielding portion 130 while surrounding the electromagnetic shielding portion 130. The cooling housing 132 may have a flow path therein, and may be cooled by a refrigerant. The cooling housing 132 may be formed of a conductive material, and may be mounted on the clamp 150. The cooling housing 132 may block radiant heat, generated by the electromagnetic shielding portion 130, to prevent damage to external components.

The cooling housing 132 may be disposed on the clamp 150 to surround the electromagnetic shielding portion 130. The cooling housing 132 may include a flow path 132a for injecting air into the electromagnetic shielding portion 130 and exhausting air from the electromagnetic shielding portion 130. Air injected into the electromagnetic shielding portion 130 may cool the antenna 110 and the upper dome 152.

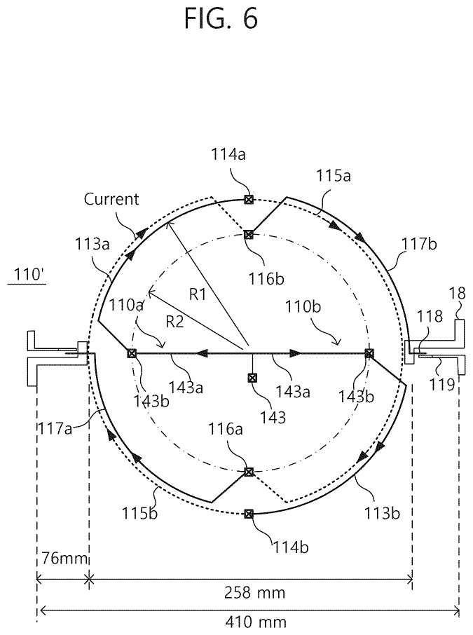

FIG. 6 is a plan view illustrating an antenna according to another embodiment of the present disclosure.

Referring to FIG. 6, an antenna 110′ may include two one-turn unit antennas 110a and 110b. The one-turn unit antennas 110a and 110b may include first curved portions 113a and 113b connected to a vertical power supply line 143b and extending from an upper surface by rotating clockwise 90 degrees along a circumference having a first radius R1; first vertical extension portions 114a and 114b changing a placement plane from the upper surface to a lower surface in the first curved portion; second curved portions 115a and 115b rotating clockwise by 180 degrees along the circumference having the first radius R1 in the first vertical extension portion; second vertical extension portions 116a and 116b continuously connected to the second curved portion, changing a radius from the first radius R1 to a second radius R2 smaller than the first radius R1, and changing a radius from the second radius R1 to the first radius R1, and third curved portions 117a and 117b extending from the upper surface by rotating 90 degrees clockwise along the circumference having the first radius R1 in the second vertical extension portion. The third curved portions 117a and 117b may be connected to a ground portion 118 extending in a radial direction. A radius of a circle connecting the pair of vertical power supply lines 143b may be R2. The pair of vertical power supply lines 143b may extend through the upper surface of the electromagnetic shielding portion 130.

An inner diameter of the electromagnetic shielding portion 130 may be 410 mm, a distance between the antenna and the electromagnetic shielding portion in an outer diameter direction may be 76 mm, and a vertical distance between the antenna and the electromagnetic shielding portion 130 may be 15 mm. A diameter of the antenna may be 258 mm. An inner diameter of the electromagnetic shielding portion 130 may be substantially the same as an inner diameter of a clamp.

Hereinafter, an experimental result, showing an HZO deposition thickness distribution of a plasma-enhanced chemical vapor deposition apparatus including an antenna having a diameter of 356 mm according to an example embodiment, will be described. An HZO deposition thickness map depending on a wafer location was investigated under a plurality of process conditions.

Referring to FIG. 1, the diameter of the antenna is 356 mm. The ratio of the diameter of the antenna to the diameter of the substrate is about 118 percent. The internal diameter of the electromagnetic shielding portion 130 is 410 mm, the outer diameter distance between the antenna and the electromagnetic shielding portion is 27 mm, and the vertical distance between the antenna and the electromagnetic shielding portion is 15 mm. The inner diameter of the electromagnetic shielding portion 130 may be substantially the same as the inner diameter of the clamp. The substrate was heated to a temperature of 320 degrees Celsius by a lamp heater. The power supplied to the antenna for inductively-coupled plasma is 1000 W. The thin film is an HZO atomic layer deposition thin film in which HfO and ZrO are alternately deposited. A process was performed at a pressure 9 mTorr and 80 mTorr. A deposition rate showed symmetry in an azimuthal direction at the pressure of 9 mTorr to 80 mTorr.

In the case of 9 mTorr, the uniformity is 7.53 percent. In this case, the deposition rate is high at an edge of the substrate. However, in the case of 80 mTorr, the deposition rate is high at a center of the substrate, and the deposition rate slightly increases at the edge of the substrate. Accordingly, the uniformity is 3.1 percent that is an improved result. When the pressure is adjusted around 80 mTorr, uniformity may be fine-tuned. The inventors interpret such improved uniformity as a result of the diameter of the antenna.

Hereinafter, an experimental result, showing an HZO deposition thickness distribution of a plasma-enhanced chemical vapor deposition apparatus including an antenna having a diameter of 258 mm according to an example embodiment, will be described.

Referring to FIG. 6, a diameter of an antenna is 258 mm. A ratio of the diameter of the antenna to a diameter of a substrate is about 86 percent. An inner diameter of an electromagnetic shielding portion 130 is 410 mm, the outer diameter distance between the antenna and the electromagnetic shielding portion is 76 mm, and the vertical distance between the antenna and the electromagnetic shielding portion is 15 mm. The inner diameter of the electromagnetic shielding portion 130 is substantially the same as an inner diameter of a clamp. The substrate was heated to a temperature of 320 degrees Celsius by a lamp heater. Power supplied to the antenna for inductively-coupled plasma is 1000 W. A thin film is an HZO atomic layer deposition thin film in which HfO and ZrO are alternately deposited. A process was performed at a plasma gas pressure of 9 mTorr of hydrogen. A deposition rate shows symmetry in the azimuthal direction at the pressure of 9 mTorr.

In the case of 9 mTorr, uniformity is 13.22 percent. In this case, a deposition rate is slightly high at an edge of the substrate.

Hereinafter, an experimental result, showing an HZO deposition thickness distribution of a plasma-enhanced chemical vapor deposition apparatus including an antenna having a diameter of 298 mm according to an example embodiment, will be described. A diameter of the antenna is 298 mm. A ratio of the diameter of the antenna to the diameter of the substrate is about 99 percent.

An inner diameter of the electromagnetic shielding portion 130 is 410 mm. The inner diameter of the electromagnetic shielding portion 130 may be substantially the same as an inner diameter of a clamp.

The substrate was heated to a temperature of 320 degrees Celsius by a lamp heater. Power supplied to the antenna for inductively-coupled plasma is 1000 W. A thin film is an HZO atomic layer deposition thin film in which HfO and ZrO are alternately deposited. A process was performed at pressures of 9 mTorr and 50 mTorr. A deposition rate shows symmetry in an azimuthal direction at the pressure of 9 mTorr. However, the deposition rate does not show azimuthal symmetry at the pressure of 50 mTorr and has a higher deposition rate at a 12 o'clock direction.

In the case of 9 mTorr, uniformity is 10.95 percent. In this case, a deposition rate is slightly high at an edge of the substrate.

In the case of 50 mTorr, the uniformity is 16.05 percent. In this case, the deposition rate is slightly high at the edge of the substrate.

According to the experimental results of the present disclosure, when the diameter of the antenna was 356 mm, azimuth symmetry and high deposition uniformity of 3.1 percent were secured. For example, when the ratio of the diameter of the antenna to the diameter of the substrate is about 120 percent, deposition uniformity as high as 3 percent may be used to manufacture a semiconductor device.

When the diameter of the antenna is 356 mm, a physical cause of the high deposition uniformity of the HZO high-κ dielectric thin film is interpreted as follows. Since a distance between the electromagnetic shielding portion and the strip line-shaped antenna is close enough that is at a level of 27 mm, a portion of the RF power of the antenna leaks into the electromagnetic shielding portion rather than being used to generate inductively-coupled plasma. Accordingly, it is interpreted that a time-varying magnetic field generated by the antenna is changed, and thus a spatial distribution of an induced electric field generated by the time-varying magnetic field is changed. It is interpreted that at pressures of several tens of mTorr or more, plasma density at the edge of the substrate is relatively reduced, as compared with the center of the substrate, to improve overall deposition uniformity. For example, in the case of an atomic layer deposition process, deposition uniformity of a thin film may be more important than a deposition rate of the thin film.

Although the present disclosure and its advantages have been described in detail, it should be understood that various changes, substitutions and alterations can be made herein without departing from the spirit and scope of the disclosure as defined by the following claims.

1. A substrate processing apparatus comprising:
a chamber having a sidewall;
a susceptor mounting a substrate inside the chamber;
an upper dome covering an upper surface of the chamber and formed of a dielectric material;
a lower dome covering a lower surface of the chamber and formed of a dielectric material;
a liner disposed on internal side of the chamber and disposed between the upper dome and the lower dome; and
an antenna disposed on the upper dome and generating inductively-coupled plasma,
wherein
a ratio of a diameter of the antenna to a diameter of the substrate is 80 percent to 120 percent.

2. The substrate processing apparatus as set forth in claim 1, wherein
the antenna comprises two one-turn (one-turn) unit antennas,
the two one-turn unit antennas are disposed to overlap each other on an upper surface and a lower surface,
the two one-turn unit antennas are connected in parallel to RF power, and
a width direction of the each of the two one-turn unit antenna stands upright vertically.

3. The substrate processing apparatus as set forth in claim 2, wherein
each of the two one-turn unit antenna is in the form of a strip line having a width greater than a thickness,
and
a ratio (W/t) of the width (W) to the thickness (t) is 10 or more.

4. The substrate processing apparatus as set forth in claim 3, wherein
each of the two one-turn unit antennas has one end connected to a pair of vertical power supply lines extending vertically, and
the pair of vertical power supply lines are connected to each other by a horizontal power supply line and then connected to the RF power.

5. The substrate processing apparatus as set forth in claim 2, further comprising:
a clamp disposed to be in contact with the upper surface of the chamber and to cover an edge of the upper dome;
an electromagnetic shielding portion disposed on the clamp and disposed to surround the antenna; and
a ground fixing portion fixing the end of each of the two one-turn antennas to the electromagnetic shielding portion,
wherein
the ground fixing portion extends from the upper surface of each of the two one-turn antenna in a radial direction, then extends to the lower surface, and then extends again from the lower surface in the radial direction.

6. The substrate processing apparatus as set forth in claim 5, further comprising:
an insulating fixing portion extending parallel to the ground fixing portion and coupled to the lower surface of the one-turn antenna to be fixed to the electromagnetic shielding portion.
